(19) United States
(12) Patent Application Publication
(10) Pub. No.: US 2012/0217158 A1
(43) Pub. Date: Aug. 30, 2012

(54) METHOD OF MANUFACTURING TITANIUM-CONTAINING SPUTTERING TARGET

(76) Inventors: Kazutoshi Takahashi, Chiba (JP); Junichi Nitta, Chiba (JP)

(21) Appl. No.: 13/503,816

(22) PCT Filed: Oct. 22, 2010
(86) PCT No.: PCT/JP2010/006262

§ 371 Date: Apr. 24, 2012

(30) Foreign Application Priority Data
Oct. 26, 2009 (JP) 2009-245325

(51) Int. Cl. C23C 14/34; B22F 3/14; B22F 3/24; C23C 14/14

(52) U.S. Cl. 204/298.13; 419/29

(57) ABSTRACT

A method of manufacturing a titanium-containing sputtering target is disclosed, with the method being capable of reducing the frequency of occurrence of abnormal discharge caused by lattice defects. A first metal powder containing a high melting point metal and a second metal powder containing titanium are manufactured. Subsequently, a mixed powder of the first metal powder and the second metal powder is sintered at a temperature of 695° C. or higher, and then heat-treated at a temperature of 685° C. or lower. After the sintering, the sintered body is heat-treated at a temperature of 685° C. or lower, thereby decreasing plate-like structures (lattice defects) in a sintered phase. Accordingly, it is possible to obtain a titanium-containing sputtering target with which abnormal discharge occurs less frequently.

### TECHNICAL FIELD

The present invention relates to a method of manufacturing a sputtering target formed of a sintered body containing titanium, and more specifically, to a method of manufacturing a titanium-containing sputtering target in which the occurrence of abnormal discharge is suppressed.

### BACKGROUND ART

In recent years, in the field of manufacturing of a liquid crystal display, a semiconductor apparatus, and the like, a sputtering target containing a high melting point metal material and titanium (Ti) has been used. For example, in the field of liquid crystal, an alloy target made of molybdenum (Mo) and titanium is a representative sputtering target, and in the filed of manufacturing of semiconductors and solar cells, an alloy made of tungsten (W) and titanium.

For example, Patent Document 1 discloses a sputtering target used for forming a thin film. The sputtering target for forming a Mo alloy film on a substrate has a composition containing Ti of 2 to 50 at % and the remaining part made of Mo and unavoidable impurities, and has a relative density of 95% or more and a bending strength of 300 MPa or more.

Further, Patent Document 2 discloses a method of manufacturing a W—Ti target, in which after a W powder and a titanium hydroxide powder each having a particle diameter of 5 μm or smaller are mixed with each other and the obtained mixed powder is subjected to dehydrogenation treatment, the resultant powder is sintered at a temperature of 1300 to 1400° C. and at 300 to 450 kg/cm², thereby obtaining a W—Ti target formed of only W- and Ti-phase structures.

Patent Document 1: Japanese Patent Application Laid-open No. 2005-29862

Patent Document 2: Japanese Patent Application Laid-open No. 2002-256422 DISCLOSURE OF THE INVENTION

### Problem to be Solved by the Invention

This type of sputtering target is manufactured mainly using a powder sintering method. For example, in a Mo—Ti binary alloy, a Mo element and a Ti element are diffused in the process of sintering so that three types of structures, a Mo simple substance phase, a Ti simple substance phase, and a Mo and Ti alloy phase are formed. In a ternary alloy and alloys including more than three elements, the number of structures further increases.

Here, in the sputtering target containing Ti, an abrupt change in crystal lattice due to the martensitic transformation of Ti easily causes lattice defects such as twin in the crystal structure. The most part of the lattice defects often appears as plate-like structures in a phase, and as an abundance ratio of the plate-like structures in the phase becomes higher, the frequency of abnormal discharge during sputtering increases. Generally, it is considered that a correlation exists between the abnormal discharge and the number of generated particles. Therefore, as the frequency of abnormal discharge increases, an amount of particles adhering to an obtained thin film increases, thus causing a problem of degraded yields.

In view of the circumstances as described above, it is an object of the present invention to provide a method of manufacturing a titanium-containing sputtering target, which is capable of reducing the frequency of occurrence of abnormal discharge caused by lattice defects.

### Means for Solving the Problem

According to an embodiment of the present invention, there is provided a method of manufacturing a titanium-containing sputtering target, including manufacturing a first metal powder containing a high melting point metal and a second metal powder containing titanium. The first metal powder and the second metal powder are mixed with each other. A mixed powder of the first metal powder and the second metal powder is pressure-sintered at a temperature of 695° C. or higher. The sintered mixed powder is heat-treated at a temperature of 500° C. or higher and 685° C. or lower.

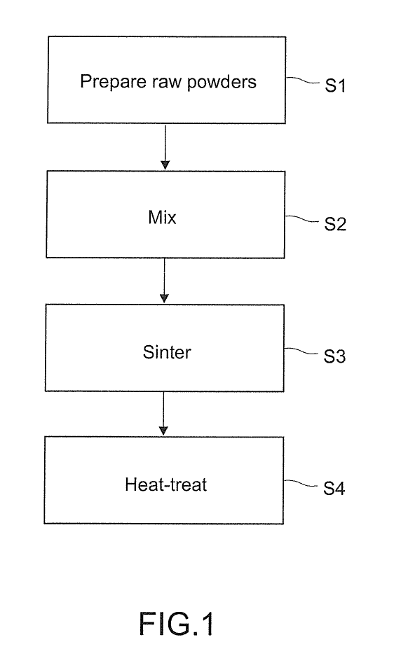

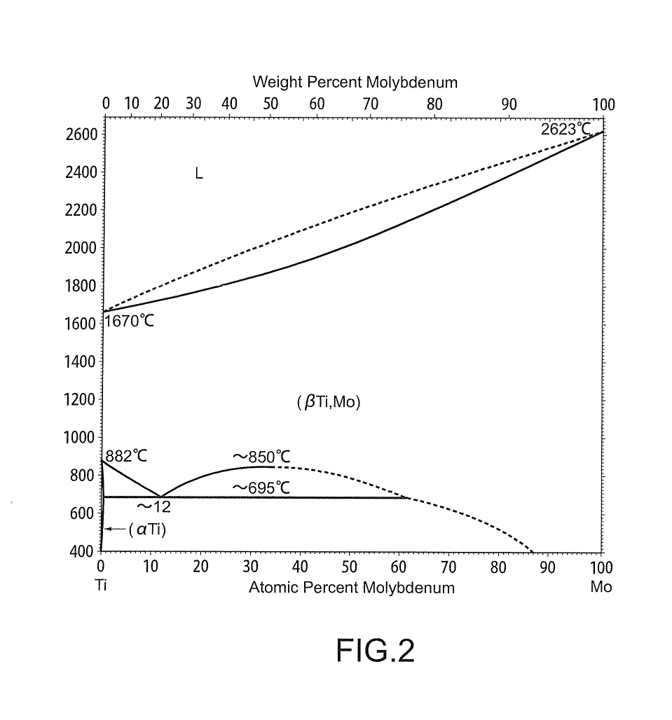

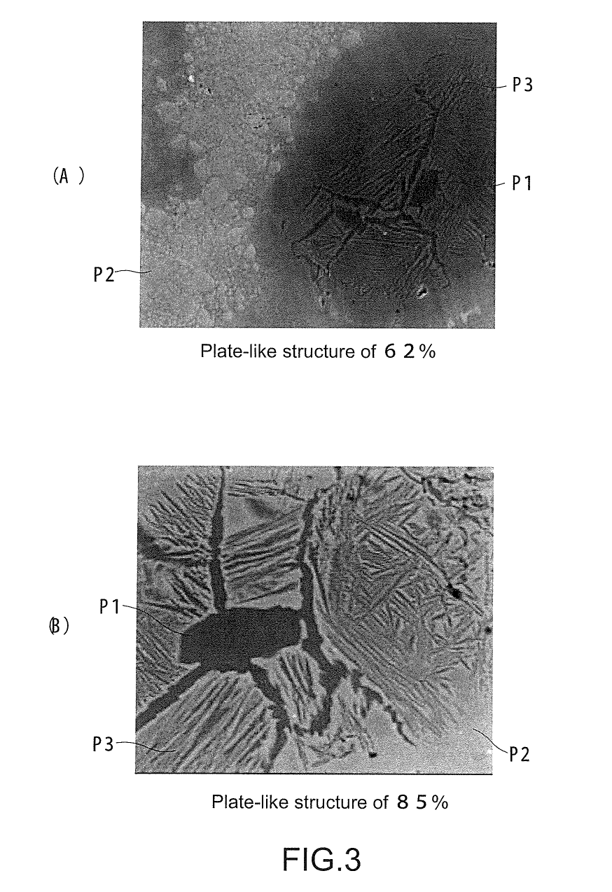

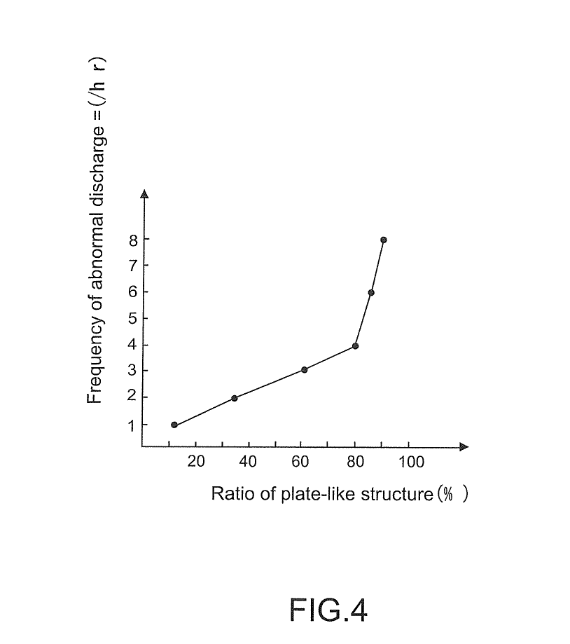

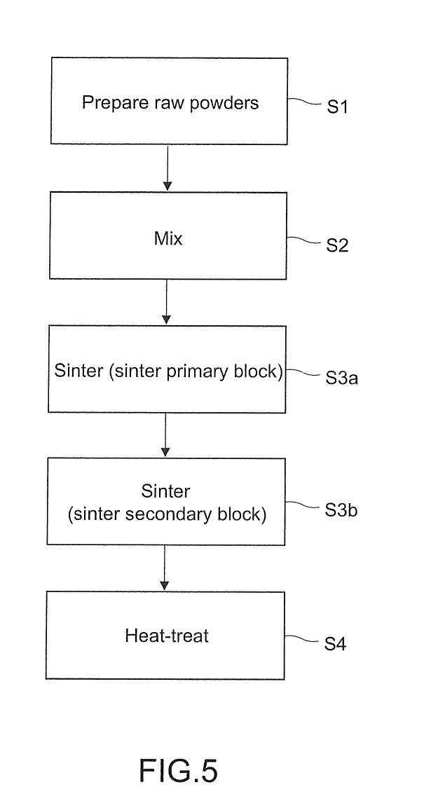

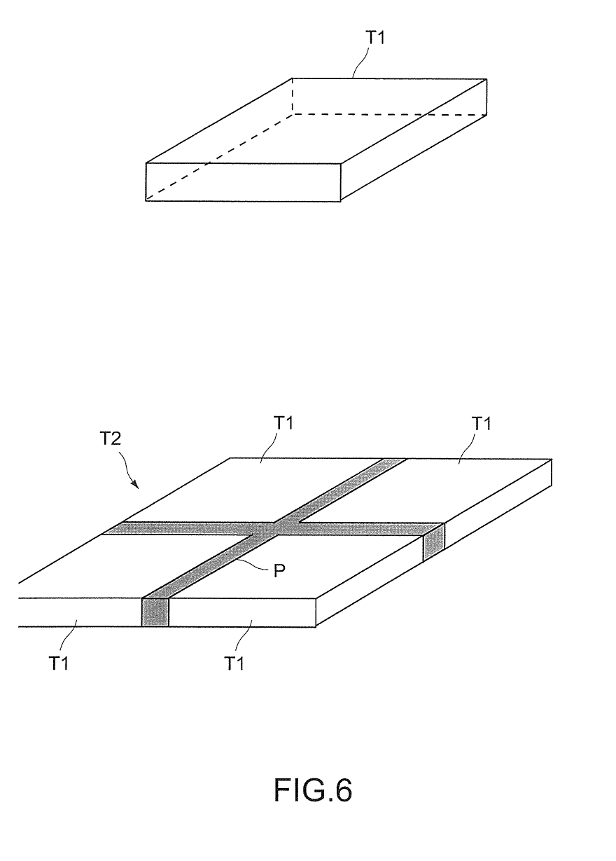

### BRIEF DESCRIPTION OF DRAWINGS

[FIG. 1] A process flow for explaining a method of manufacturing a titanium-containing sputtering target according to a first embodiment of the present invention.

[FIG. 2] A Ti—Mo-based equilibrium diagram.

[FIG. 3] Photographs of structure samples of sintered bodies manufactured by the above-mentioned method of manufacturing a sputtering target, in which part (A) shows a sample of a plate-like structure of 62%, and part (B) is a sample of a plate-like structure of 85%.

[FIG. 4] A diagram showing a relationship between a ratio of plate-like structures and the frequency of abnormal discharge.

[FIG. 5] A process flow for explaining a method of manufacturing a titanium-containing sputtering target according to a second embodiment of the present invention.

[FIG. 6] Schematic perspective views of a primary block and a secondary block that constitute a sputtering target, in which part (A) shows the primary block and part (B) shows the secondary block.

### BEST MODES FOR CARRYING OUT THE INVENTION

According to an embodiment of the present invention, there is provided a method of manufacturing a titanium-containing sputtering target, including manufacturing a first metal powder containing a high melting point metal and a second metal powder containing titanium. The first metal powder and the second metal powder are mixed with each other. A mixed powder of the first metal powder and the second metal powder is pressure-sintered at a temperature of 695° C. or higher. The sintered mixed powder is heat-treated at a temperature of 500° C. or higher and 685° C. or lower.

In the method of manufacturing a titanium-containing sputtering target, after sintering, the sintered body is heat-treated at a temperature of 500° C. or higher and 685° C. or lower, thereby decreasing plate-like structures (lattice defects) in a sintered phase. Accordingly, it is possible to obtain a titanium-containing sputtering target with which abnormal discharge occurs less frequently.

The high melting point metal that constitutes the first metal powder includes molybdenum (Mo), tungsten (W), tantalum (Ta), and the like. A mixture ratio of the first metal powder and the second metal powder is not particularly limited, and a main component may be the first metal powder or the second metal powder.

The pressure-sintering a mixed powder may include a first sintering step of sintering a primary block of the mixed powder, and a second sintering step of sintering a secondary block obtained by bonding a plurality of primary blocks to each other with the mixed powder.

Accordingly, a relatively large-sized sputtering target can also be manufactured with ease.

The second sintering step may be performed at a temperature higher than that in the first sintering step.

Accordingly, a bonding strength between the primary blocks can be enhanced, and the secondary block can be stably manufactured.

In the sintering step described above, the mixed powder is sintered with a predetermined pressure being applied thereto. In other words, the titanium-containing sputtering target is manufactured by a pressure sintering method. Accordingly, a high density of the sintered body can be achieved. Examples of the pressure sintering method include hot pressing, HIP (hot isostatic pressing), and extrusion molding.

Hereinafter, embodiments of the present invention will be described based on the drawings.

### First Embodiment

FIG. 1 is a process flow for explaining a method of manufacturing a titanium-containing sputtering target (hereinafter, referred to simply as sputtering target) according to a first embodiment of the present invention. The method of manufacturing a titanium-containing sputtering target according to this embodiment includes a step (S1) of preparing raw powders, a step (S2) of mixing the raw powders, a step (S3) of sintering the raw powders, and a step (S4) of heat-treating a sintered body.

For the raw powders, a first metal powder and a second metal powder are mainly used. The first metal powder is a metal powder containing a high melting point metal, and the second metal powder is a metal powder containing titanium. In this embodiment, a metal powder containing molybdenum (Mo) is used for the first metal powder.

To manufacture the first metal powder and the second metal powder, a dry method or a wet method is used. For example, a decomposition gas such as hydrogen (H₂), carbon monoxide (CO), or ammonia (NH₃) is used to reduce molybdenum oxide (MoO₃), to thereby manufacture a fine powder of metal molybdenum. In this embodiment, a molybdenum powder having a particle size of about 5 μm and a titanium powder having a particle size of about 45 μm are used.

The high melting point metal that constitutes the first metal powder is not limited to molybdenum, and may be tungsten (W) or tantalum (Ta). Also in those cases, a fine metal powder can be manufactured by an operation similar to that described above.

The titanium powder may be manufactured by gas atomization. The atomization is a method of, for example, by spraying an inert gas or the like to a molten metal that flows out from a nozzle, pulverizing the molten metal to be solidified as fine droplets. Use of an inert gas as a coolant gas allows oxidation of metal to be suppressed and a metal fine powder having relatively low hardness to be easily obtained. The titanium powder having hardness of 70 or higher and 250 or lower in terms of Vickers hardness (Hv) can be used.

It should be noted that the first and second metal powders may be manufactured in advance before the manufacture of a target, or commercially available ones may be used.

Next, the manufactured first and second powders to be mixed are prepared at a predetermined ratio and then mixed (Step S2). The preparation ratio of the first and second metal powders is not particularly limited and can be set as appropriate in accordance with a desired thin-film composition. For example, in the case where a thin film made of a high melting point metal is formed, a mixed powder containing the first metal powder as a main component can be manufactured. To mix metal powders, various types of mixing machines can be used.

Subsequently, the manufactured mixed powder is sintered to have a predetermined shape (Step S3).

In this embodiment, a pressure sintering method of sintering the above-mentioned mixed powder while applying a predetermined pressure (load) thereto is adopted. Examples of the pressure sintering method include hot pressing, HIP (hot isostatic pressing), and extrusion molding. In this embodiment, hot pressing is adopted. The shape of the sintered body is plate-like, but it is not limited thereto as a matter of course. Further, a pressure at a time of sintering is 100 MPa or higher and 200 MPa or lower (atmospheric pressure of 1000 to 2000), but it is not limited thereto. The pressure can be set as appropriate in a range of 20 MPa to 200 MPa.

A sintering temperature is set to 695° C. or higher. In the case where the sintering temperature is lower than 695° C., a high-density sintered body cannot be obtained by an ordinary sintering method. The sintering temperature at which a sintered body having a relative density of 95% or more can be obtained is, for example, 700° C. or higher and 1400° C. or lower, and in this embodiment, 1000° C.

Next, a step of heat-treating the manufactured sintered body is performed (Step S4). This heat treatment is intended for structure control of a sintered phase and is for annealing of the sintered body for a predetermined period of time at a temperature of 685° C. or lower, which is lower than an eutectoid line of a Ti—Mo alloy. Hereinafter, the signification of the heat treatment step will be described with reference to FIG. 2.

FIG. 2 is an equilibrium diagram of a typical Ti—Mo-based alloy. Pure Ti has a phase transformation point at about 882° C. and is transformed from αTi into βTi by being heated to a temperature higher than that of the transformation point. The crystal structure of αTi is a hexagonal close-packed structure (cph), and the crystal structure of βTi is a body-centered cubic structure (bcc). The phase transformation from βTi to αTi involves martensitic transformation in many cases, which easily causes lattice defects such as twin before and after the transformation. On the other hand, a Ti—Mo alloy having a Mo content of about 60 at % or less has an eutectoid line at about 695° C. In the case where the Ti—Mo alloy is cooled from a temperature at the eutectoid line or above, an eutectoid reaction according to a composition ratio between a Ti element and a Mo element is caused. The eutectoid reaction refers to a phenomenon of precipitating another phase in a solid phase and also includes a case where a precipitated structure is a martensitic structure of a titanium phase.

Martensitic titanium causes lattice defects such as twin, and this lattice defects appear as plate-like structures (heterogeneous phase) in a sintered structure. It is known that as to a sputtering target manufactured by sintering, as an abundance ratio of the heterogeneous phase becomes higher, the frequency of abnormal discharge during sputtering increases. The abnormal discharge means arcing that locally occurs on a surface of the target, and the arcing is also considered as one factor that causes particles. Therefore, to stably form a high-quality thin film, it is important to what extent the occurrence of plate-like structures in a sintered phase is suppressed.

In this regard, in this embodiment, the sintered body is heat-treated at a temperature of 685° C. or lower after sintering. By the heat treatment, atoms in a solid phase are diffused again, with the result that an internal stress is reduced and the uniform structure is achieved. In addition, the ratio of the heterogeneous phase (plate-like structure) in the sintered phase can be suppressed to be 80% or lower, which makes it possible to effectively suppress abnormal discharge at a time of sputtering of a sputtering target formed of the sintered body.

The heat treatment temperature exceeding 685° C. approaches or exceeds the eutectoid line. Therefore, the ratio of the plate-like structures is adversely increased instead of a decrease thereof. Further, the heat treatment temperature can be set as appropriate within a range in which an anneal effect is obtained, and is set to, for example, 500° C. or higher and 685° C. or lower.

The heat treatment time can be set as appropriate in consideration of the sintering temperature and the productivity. A longer heat treatment time can enhance an effect of reducing the plate-like structures more. For example, the heat treatment time can be set to 6 hours or more and 72 hours or less, and in this embodiment, 12 hours. The pressure for heat treatment may be an atmospheric pressure or vacuum. Further, an atmosphere of the heat treatment can be set to an atmosphere of an inert gas such as nitrogen or argon.

FIG. 3 are photographs of a structure of a sintered body of a Ti—Mo alloy. FIG. 3(A) is a photograph of a structure sample of a plate-like structure of 62%, and FIG. 3(B) is a photograph of a structure sample of a plate-like structure of 85%. In those figures, an area P1 is a Ti phase, an area P2 is a Mo phase, and an area P3 appearing in a needle-like stripe pattern is a plate-like structure.

Further, FIG. 4 shows experimental results showing a relationship between an abundance ratio of the plate-like structures and the frequency of abnormal discharge. In the experiment, a plurality of samples with different ratios of plate-like structures were mounted on a cathode portion of a sputtering apparatus and sputtered under conditions of a sputtering gas of Ar, a sputtering pressure of 0.5 Pa, and sputtering power of 10.8 W/cm².

As is apparent from the results of FIG. 4, there is a tendency that as the ratio of plate-like structures increases, the frequency of abnormal discharge at a time of sputtering also increases. In particular, when the ratio of plate-like structures exceeds 80%, the frequency of abnormal discharge at a time of sputtering sharply increases. The abnormal discharge is known to have a strong correlation with the occurrence of particles, and the suppression of the abnormal discharge allows the formation of a high-grade, high-quality thin film. Therefore, the suppression of the ratio of plate-like structures in the sintered phase to be 80% or lower allows the stable formation of a film, which is less subjected to an influence of abnormal discharge.

As described above, according to this embodiment, a titanium-containing sputtering target having less heterogeneous phase can be manufactured. Accordingly, it is possible to suppress the occurrence of abnormal discharge and stably manufacture a high-quality thin film.

### Second Embodiment

FIG. 5 is a process flow for explaining a method of manufacturing a sputtering target according to a first embodiment of the present invention. The method of manufacturing a sputtering target in this embodiment includes a step (S1) of preparing raw powders, a step (S2) of mixing the raw powders, a step (S3a) of sintering a primary block, a step (S3b) of sintering a secondary block, and a step (S4) of heat-treating a sintered body. In other words, in this embodiment, the step of sintering a mixed powder of a Ti powder and a Mo powder includes a first sintering step of sintering a primary block of the mixed powder described above and a second sintering step of sintering a secondary block obtained by bonding a plurality of primary blocks described above with the mixed powder.

The method of manufacturing a sputtering target in this embodiment is different from that of the above-mentioned first embodiment in that the step of sintering the raw powders is divided into the step (S3a) of manufacturing a primary block sintered body and the step (S3b) of manufacturing a secondary block sintered body. This embodiment can be applied to the manufacturing of a sputtering target having a relatively large target size.

FIG. 6 are schematic perspective views of sintered bodies manufactured in this embodiment, and part (A) shows a primary block T1, and part (B) shows a secondary block T2. The primary block T1 is manufactured through the steps S1 to S3a. The steps S1 to S3a are the same as in the above-mentioned first embodiment. In this embodiment, the primary block T1 is formed into a rectangular plate-like shape.

The secondary block T2 is a combined body constituted of a plurality of primary blocks T1. To bond the primary blocks T1 to one another, a mixed powder of Ti and Mo that serves as a raw powder of the primary block T1 is used. The mixed powder is sintered in a state of being interposed between the primary blocks T1 (Step S3b), thus functioning a bonding layer P that bonds adjacent primary blocks T1 to one another.

The bonding layer P may be sintered with a predetermined magnitude of load being applied thereto from the adjacent primary blocks T1. Further, the bonding layer P may be preliminarily molded into a desired shape. The thickness (or width) of the bonding layer P can be set to an arbitrary size and is not limited to the example shown in the figures. Further, the arrangement example, the number, and the like of primary blocks T1 to be used for forming the secondary block T2 are also not limited to the example shown in the figures.

In this embodiment, a sintering temperature in the step of sintering the secondary block T2 is set to be higher than that of the primary block T1. Accordingly, the reliability of bonding is enhanced and a large-sized target excellent in mechanical strength can be manufactured. As long as a required bonding strength is obtained, the sintering temperature of the secondary block T2 may be equal to or lower than that of the primary block T1.

After the sintering of the secondary block T2, the secondary block T2 is heat-treated at a temperature of 685° C. or lower (Step S4). This heat treatment step is performed similarly to the above-mentioned first embodiment. Accordingly, plate-like structures of Ti that are precipitated in a solid phase can be extinguished, and an excellent sintered body having a lower abundance ratio of the heterogeneous phase can be obtained.

As described above, according to this embodiment, even a relatively large-sized sputtering target having a length of 1 m or more in a longitudinal side thereof can be manufactured, for example.

Hereinabove, the embodiments of the present invention have been described, but the present invention is not limited thereto. The present invention can be variously modified based on the technical idea of the present invention.

For example, in the embodiments described above, the Ti—Mo-based sputtering target has been described. However, instead of the Ti—Mo-based sputtering target, a Ti—W-based sputtering target is also applicable.

Further, in the embodiments described above, hot pressing is used in the sintering step, but the sintering step is not limited thereto and HIP, extrusion molding, and the like are applicable.

### DESCRIPTION OF SYMBOLS

P1 Ti phase

P2 Mo phase

P3 plate-like structure

T1 primary block

T2 secondary block

P bonding layer

1. A titanium-containing sputtering target, manufactured by heat-training a pressure-sintered body made of a mixed powder of a first metal powder and a second metal powder, the first metal powder containing a high melting point metal, the second metal powder containing titanium, and having a ratio of 80% or less of a plate-like structure in a sintered phase.

2. The titanium-containing sputtering target according to claim 1, wherein
the pressure-sintered body is pressure-sintered at a temperature of 695° C. or higher and heat-treated at a temperature of 500° C. or higher and 685° C. or lower.

3. The titanium-containing sputtering target according to claim 1, wherein
the high melting point metal is molybdenum or tungsten.

4. A method of manufacturing a titanium-containing sputtering target, comprising:
manufacturing a first metal powder containing a high melting point metal and a second metal powder containing titanium;
mixing the first metal powder and the second metal powder with each other;
pressure-sintering a mixed powder of the first metal powder and the second metal powder at a temperature of 695° C. or higher; and
heat-treating the sintered mixed powder at a temperature of 500° C. or higher and 685° C. or lower.

5. The method of manufacturing a titanium-containing sputtering target according to claim 4, wherein
the sintering a mixed powder includes
a first sintering step of sintering a primary block of the mixed powder, and
a second sintering step of sintering a secondary block obtained by bonding a plurality of primary blocks to each other with the mixed powder.

6. The method of manufacturing a titanium-containing sputtering target according to claim 5, wherein
the second sintering step is performed at a temperature higher than that in the first sintering step.

7. The method of manufacturing a titanium-containing sputtering target according to claim 4, wherein
the sintered mixed powder is heat-treated at a temperature of 500° C. or higher and 685° C. or lower, to suppress a ratio of a plate-like structure in a sintered phase to be 80% or lower.

8. The method of manufacturing a titanium-containing sputtering target according to claim 4, wherein
the high melting point metal is molybdenum or tungsten.
